(19) United States
(12) Patent Application Publication
(10) Pub. No.: US 2012/0055691 A1
(43) Pub. Date: Mar. 8, 2012

(54) HOUSING AND METHOD FOR MANUFACTURING HOUSING

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); MAN-XI ZHANG, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 12/981,718

(22) Filed: Dec. 30, 2010

(30) Foreign Application Priority Data
Sep. 3, 2010 (CN) 201010271819.3

(51) Int. Cl. H01L 23/06; C23C 14/08; C23C 14/02; C23C 14/35

(52) U.S. Cl. 174/50; 204/192.15

(57) ABSTRACT

A housing includes a substrate; an aluminum layer deposited on the substrate; and an oxygen ion implantation layer deposited on the aluminum layer. The oxygen ion implantation layer comprising saturated aluminum oxide. The saturated Al₂O₃ can improve the compactness of the oxygen ion implantation layer. Thus, the corrosion resistance of the housing can be improved.

### BACKGROUND

1. Technical Field

The disclosure generally relates to housings for electronic devices and method for manufacturing the housings.

2. Description of Related Art

With the development of wireless communication and information processing technology, portable electronic devices such as mobile telephones and electronic notebooks are now in widespread use. Magnesium or magnesium alloy have good heat dissipation and can effectively shield electromagnetic interference so magnesium and magnesium alloy are widely used to manufacture housings of the portable electronic devices. However, magnesium and magnesium alloy have low corrosion resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing and method for manufacturing the housing. Moreover, in the drawings like reference numerals designate corresponding parts throughout the several views. Wherever possible, the same reference numbers are used throughout the drawings to refer to the same or like elements of an embodiment.

FIG. 1 illustrates a cross-sectional view of an exemplary embodiment of a housing.

FIG. 2 illustrates a cross-sectional view of an alternative exemplary embodiment of a housing.

FIG. 3 is a schematic view of a magnetron sputtering coating machine for manufacturing the housing in FIG. 1.

### DETAILED DESCRIPTION

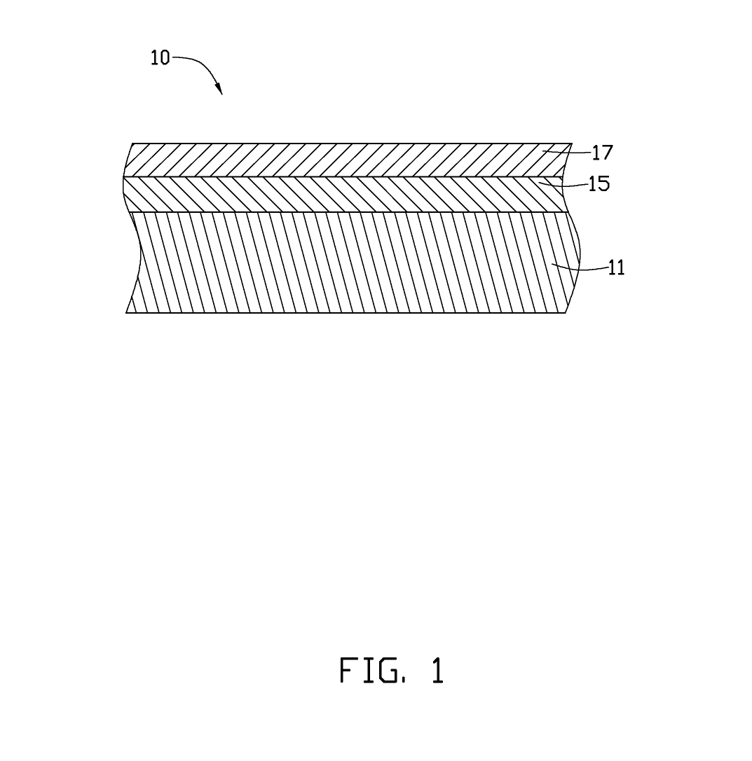

Referring to FIG. 1, in an exemplary embodiment, a housing 10 includes a substrate 11, an aluminum layer 15 deposited on substrate 11, and an oxygen ion implantation layer 17 deposited on the aluminum layer 15. The housing 10 may be used for an electronic device. The substrate 11 may be made of magnesium or magnesium alloy. The aluminum layer 15 is made of aluminum. The aluminum layer 15 has a thickness ranging from about 0.5 micrometer to about 1.0 micrometer. The oxygen ion implantation layer 17 comprises saturated aluminum oxide (Al2O3).

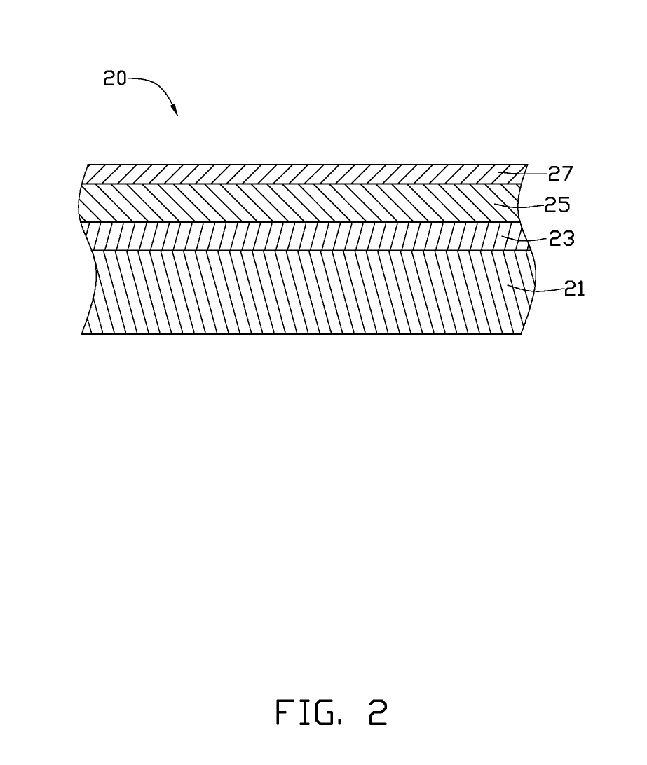

An alternative exemplary embodiment of a housing 20 is illustrated in FIG. 2 including a substrate 21, a tin layer 23 deposited on the substrate 21, an aluminum layer 25 deposited on tin layer 23, and an oxygen ion implantation layer 27 deposited on the aluminum layer 25. The housing 20 may be for an electronic device. The substrate 21 may be made of magnesium or magnesium alloy. The tin layer 23 is made of tin. The tin layer 23 has a thickness ranging from about 200 nanometers to about 600 nanometers. The aluminum layer 25 is made of aluminum. The aluminum layer 25 has a thickness ranging from about 0.5 micrometer to about 1.0 micrometer. The oxygen ion implantation layer 27 comprises saturated aluminum oxide (Al2O3).

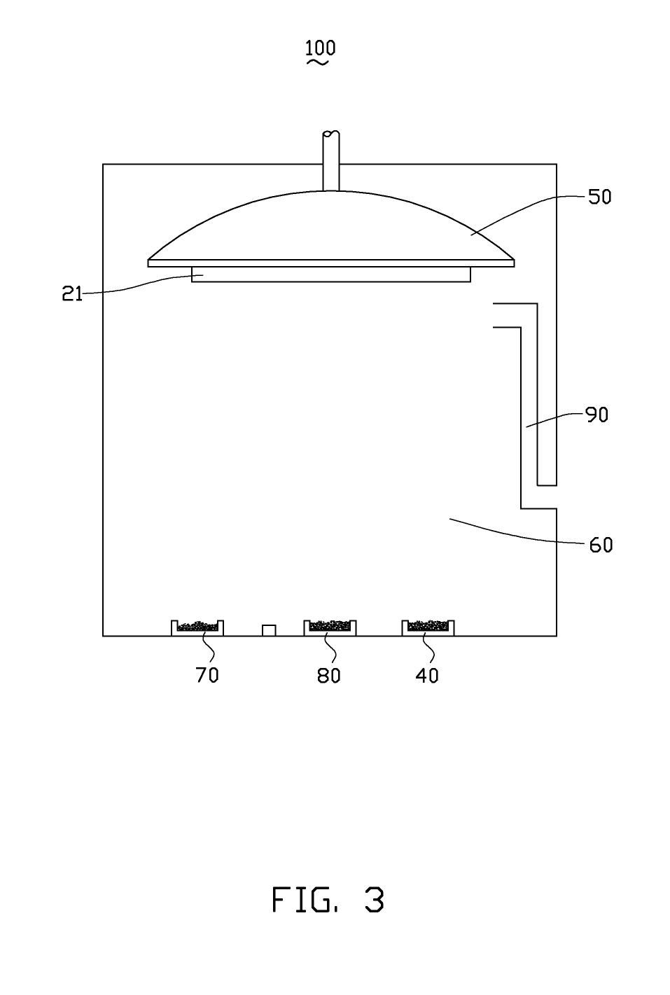

Referring to FIG. 3, a method for manufacturing the housing 20 includes at least the following steps.

A substrate 21 is provided. The substrate 21 may be made of magnesium and magnesium alloy, and may be molded by a punching method.

The substrate 21 is pretreated. First, the substrate 21 is washed with a solution (e.g., alcohol or acetone) in an ultrasonic cleaner to remove grease, dirt, and/or impurities. The substrate 21 is then dried. Finally, the substrate 21 is cleaned by argon plasma cleaning. The substrate 21 is retained on a rotating bracket 50 in a vacuum chamber 60 of a magnetron sputtering process coating machine 100. The vacuum level of the vacuum chamber 60 is adjusted to about 8.0×10⁻³ Pa. Argon is fed into the vacuum chamber 60 at a flux of about 300 Standard Cubic Centimeters per Minute (sccm) to about 600 sccm from a gas inlet 90. A bias voltage is applied to the substrate 21 in a range from about −300 volts to about −800 volts for about 3 minutes to about 10 minutes. The substrate 21 is washed by argon plasma to further remove the grease or dirt. Thus, the binding force between the substrate 21 and the aluminum layer 15 is enhanced.

A tin layer 23 is deposited on the substrate 21 by magnetron sputtering process. The temperature in the vacuum chamber 60 is adjusted to about 50° C. (Celsius degrees) to about 180° C. Argon is fed into the vacuum chamber 60 at a flux from about 100 sccm to about 300 sccm from the gas inlet 90. A tin target 70 is evaporated at a power from about 5 kw to about 10 kw. A bias voltage applied to the substrate 21 is in a range from about −50 volts to about −300 volts for a time of about 30 min to about 60 min, to deposit the tin layer 23 on the substrate 21.

An aluminum layer 25 is deposited on the tin layer 23 by magnetron sputtering process. The temperature in the vacuum chamber 60 is adjusted to about 50° C. to about 180° C. Argon is fed into the vacuum chamber 60 at a flux from about 100 sccm to about 300 sccm from the gas inlet 90. An aluminum target 80 is evaporated at a power from about 5 kw to about 10 kw. A bias voltage applied to the substrate 21 is in a range from about −50 volts to about −300 volts for a time of about 30 min to about 90 min, to deposit the aluminum layer 25 on the substrate 21.

The tin can be quickly diffused under a low temperature of about 210° C., so the tin layer 23 can improve the binding force between the aluminum layer 25 and the substrate 21. Additionally, the tin layer 23 can decrease pores on the substrate 21, to improve the corrosion resistance of the substrate 21.

An oxygen ion implantation layer 27 is formed on the aluminum layer 25 by ion implantation process. Oxygen (99.999%) is fed to an ion source 40 in the vacuum coating machine 100 from the gas inlet 90. The ion source 40 is started at a power from about 0.5 kw to about 5 kw for about 30 minutes to about 120 minutes, to produce oxygen ions. The oxygen ions produced by the ion source 40, are then accelerated in a high-voltage field so the oxygen ions become oxygen ion beams with a high energy ranging from tens of thousands volts to millions volts, until the oxygen beams emitted to the aluminum layer 25, i.e., the oxygen ions are implanted into the aluminum layer 25. During this processing, the physical properties of the aluminum layer 25 changes, to produce the ion implantation layer 27 mainly comprising of saturated aluminum oxide (Al2O3). The saturated Al₂O₃ can improve the compactness of the oxygen ion implantation layer 27. Thus, the corrosion resistance of the housing 20 can be improved.

Depending on the embodiment, certain of the steps described below may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

It is to be understood, however, that even through numerous characteristics and advantages of the disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing, comprising:
a substrate;
an aluminum layer deposited on the substrate; and
an oxygen ion implantation layer deposited on the aluminum layer;
wherein the oxygen ion implantation layer comprises saturated aluminum oxide.

2. The housing as claimed in claim 1, wherein the substrate is made of magnesium or magnesium alloy.

3. The housing as claimed in claim 1, wherein the aluminum layer has a thickness ranging from about 0.5 micrometer to about 1.0 micrometer.

4. The housing as claimed in claim 1, further comprising a tin layer deposited on the substrate between the substrate and the aluminum layer.

5. The housing as claimed in claim 4, wherein the tin layer has a thickness ranging from about 200 nanometers to about 600 nanometers.

6. A method for manufacturing a housing, the method comprising:
providing a substrate made of magnesium and magnesium or aluminum in a vacuum chamber;
depositing an aluminum layer on the substrate, wherein the aluminum layer is deposited on the substrate with an aluminum target by magnetron sputtering process; and
forming an oxygen ion implantation layer on the aluminum layer, wherein the oxygen ion implantation layer is formed on the aluminum layer by implanting ions of oxygen into the aluminum layer, and the oxygen ion implantation layer comprises saturated aluminum oxide.

7. The method of claim 6, wherein during depositing the aluminum layer on the substrate, first providing a vacuum coating machine having a vacuum chamber, the aluminum target and a rotating bracket, the aluminum target and the rotating bracket are both located in the vacuum chamber; the substrate is then retained on the rotating bracket; the temperature in the vacuum chamber is adjusted to about 50° C. to about 180° C.; argon is fed into the vacuum chamber at a flux of about 100 sccm to about 300 sccm; a bias voltage is applied to the substrate in a range from about −50 volts to about −300 volts; the aluminum target is evaporated at a power from about 5 kw to about 10 kw for about 30 minutes to about 90 minutes, to deposit the aluminum layer on the substrate.

8. The method of claim 6, wherein during forming the oxygen ion implantation layer on the aluminum layer, oxygen is fed to an ion source in the vacuum coating machine, the ion source is started at a power from about 0.5 kw to about 5 kw for about 30 minutes to about 120 minutes, to produce oxygen ions which are implanted into the aluminum layer to produce the oxygen ion implantation layer.

9. The method of claim 6, further comprising epositing a tin layer on the substrate before depositing aluminum layer on the substrate.

10. The method of claim 9, wherein during depositing the tin layer on the substrate, providing a vacuum coating machine having a vacuum chamber, a tin target and a rotating bracket, the aluminum target and the rotating bracket are both located in the vacuum chamber; the substrate is retained on the rotating bracket; the temperature in the vacuum chamber is adjusted to about 50° C. to about 180° C.; argon is fed into the vacuum chamber at a flux of about 100 sccm to about 300 sccm; a bias voltage is applied to the substrate in a range from about −50 volts to about −300 volts; the tin target is evaporated at a power from about 5 kw to about 10 kw for about 30 minutes to about 90 minutes, to deposit the tin layer on the substrate.

11. The method of claim 9, further comprising pretreating the substrate before depositing the tin layer on the substrate; pretreating the substrate comprising a step which the substrate is washed with a solution in an ultrasonic cleaner to remove grease, dirt, and/or impurities.

12. The method of claim 11, wherein pretreating the substrate further comprises drying the substrate after washing the substrate.

13. The method of claim 12, wherein pretreating the substrate further comprises cleaning the substrate by argon plasma cleaning after the drying the substrate.
